(19) United States
(12) Patent Application Publication
(10) Pub. No.: US 2009/0179212 A1
(43) Pub. Date: Jul. 16, 2009

(54) LED and phosphor for short-wave semiconductor

(76) Inventors: Soshchin Naum, Changhua City (TW); Wei-Hung Lo, Taipei City (TW); Chi-Ruei Tsai, Taipei City (TW)

Correspondence Address: The Weintraub Group, P.L.C., 28580 Orchard Lake Road, Suite 140, Farmington Hills, MI, 48334, US

(21) Appl. No.: 12/005,408

(22) Filed: Dec. 27, 2007

(30) Foreign Application Priority Data
Dec. 28, 2006 (TW) 095149447

(51) Int. Cl. H01L 33/00; C09K 11/86

(52) U.S. Cl. 257/98; 252/301.4 H; 257/E33.061

(57) ABSTRACT

A phosphor for short-wave semiconductor LEDs to create white radiation that comes from the lumen of the phosphor and the blue radiation of the heterojunction absorbed by the phosphor. The phosphor is prepared from a YAG-based substrate and added with N⁻³ and F⁻¹, having the chemical formula of (ΣLn)₃Al₅O_{12-δ}N⁻³_{δ/2}F⁻¹_{δ/2}, in which ΣLn=Y_{1-x-y-z}GdₓLu_{y}Ce_{z}. The phosphor has high lumen brightness and the characteristics of high stability of light chromaticity and high durability.

### BACKGROUND OF THE INVENTION

1. Field of the Invention

The present invention relates to light emitting technology and more particularly, to a phosphor for use in an InGaN heterostructure-based light emitting diode to provide a high luminous intensity 500 cd (2θ=30°) and a high light output efficiency η≧60 lm/w. The lumen intensity remains unchanged when the LED is working continuously for more than 10,000 hours.

2. Description of the Related Art

Following progress of semiconductor technology, semiconductor illumination technology (“solid light source” technology) has been developed rapidly. In this field, people keep studying various semiconductor light sources, including blue, green, yellow, orange-yellow and red color. At the same time, people pay more attention to the fabrication of white light sources: either in red, green and blue heterostructures (P-N junction) or blue heterostructure with an organic film of optical structure. In the layer of organic film, there is distributed a luminous material powder. The initial short-wave radiation of the heterostructure causes strong photoluminescence of the powder. When compared to long-wave of excited light, photoluminescence has a relatively longer wavelength, such as λ=540˜580 nm. Normally, to regular InGaN heterostructure, the blue radiation is λ=450˜475 nm.

U.S. Pat. No. 6,614,179, (issued to Suji Nakamura et. al., of Nichia Chemical, Japan on Feb. 9, 2003), entitled “Light emitting device with blue light LED and phosphor components”, discloses the fabrication of a white LED from YAG-based luminous material. The standard chemical formula of YAG is Y₃Al₅O₁₂:Ce. The heterostructure blue radiation is mixed with the excited light of the YAG:Ce powder, producing white light. The light emitting material according to this patent has wide application value. However, it still has numerous drawbacks as follows: limited radiation spectral zone, mainly in yellow green spectrum λ=530˜560 nm; low lumen intensity and low quantum radiation output q≦0.65; unstability of light when working for a long period of time.

Many improvements are disclosed and intended to eliminate the drawbacks of the phosphor according to U.S. Pat. No. 6,614,179. Taiwan Patent N228324, issued to the present inventor, and US patent application number 2005/0088077A1, filed by the present inventor, both disclose a non-stoichiometric phosphor (Ln₂O₃)_{3±α}(Al₂O₃)_{5±β}. To control the radiation spectrum of the phosphor, Gd is added. Further, the ratio of stoichiometric constant α and β adjusts the quantum radiation output. This material has a high quantum output q≧0.85, and the spectrum varies within λ=530˜580 nm. The phosphor according to the above patent has the characteristic that the light intensity of the radiation is constant when working continuously for 1000˜10000 hours.

The known phosphor (Ln₂O₃)_{3±α}(Al₂O₃)_{5±β} has the drawbacks: when the material is heated at 120˜140° C., the lumen intensity is reduced, and the brightness may become λ=10˜15% when T=160° C.

Therefore, it is desirable to provide an anti-heat phosphor for white LED that has a wide spectrum adjustment range under a same radiation wave length and, which improves yellow, orange-yellow and red visible spectrum lumen efficiency and maintains the brightness during long working of the white LED.

### SUMMARY OF THE INVENTION

The present invention has been accomplished under the circumstances in view. It is therefore the main object of the present invention to provide a phosphor for used in a short-wave semiconductor, which is heat resistant, and has a wide spectrum adjustment range under a same radiation wave length.

It is therefore another object of the present invention to provide a phosphor for used in a short-wave semiconductor, which improves the lumen efficiency of yellow, orange-yellow and red visible spectrum.

To achieve these and other objects of the present invention, the phosphor for use in a short-wave semiconductor light emitting diode comprises a substrate prepared from an oxide of rear-earth elements of aluminum, and an activating agent prepared from cerium, wherein the phosphor contains nitrogen and fluorine and the chemical formula of the phosphor is (ΣLn)₃Al₅O_{12-δ}N⁻³_{δ/2}F⁻¹_{δ/2}, in which ΣLn=Y_{1-x-y-z}GdₓLu_{y}Ce_{z}.

Further, the chemical index varies as: x=0.01˜0.4, y=0.001˜0.1, z=0.001˜0.4, and δ=0.001˜0.005.

Further, the composition of the phosphor is in conformity with the inequality: 0.005≦Ce/(Y+Gd+Lu+Ce)≦0.05.

Further , the material of the phosphor absorbs short-wave λ=440˜480 nm from an InGaN semiconductor LED, and the composition of the phosphor is in conformity with the inequality: 0.02≦Lu/(Y+Gd+Lu+Ce)≦0.10.

Further, the material of the phosphor gives light in yellow green spectral zone of wavelength λ=530˜590 nm, and the composition of the phosphor is in conformity with the inequality: 0.05≦Gd/(Y+Gd+Lu+Ce)≦0.30.

Further, the material of the phosphor has a lumen equivalent value 290≦Q1≦360 lm/w, the chemical index of the radiation of the phosphor is: 0.001≦δ≦0.015, and the substrate material F⁻¹ has the same content.

Further, the powder particles of the phosphor have an elliptic shape, a medium size: 1 μm≦d₅₀≦2 μm, and a specific surface area: S≧38×10³ cm²/cm³.

Further, the afterglow time of the radiation of Ce⁺³ is: τₑ=72 ns, and the afterglow time is reduced to below τₑ=72 ns when the nitrogen content in the substrate is increased.

To achieve the aforesaid and other objects of the present invention, the light emitting diode comprises an InGaN heterostructure, and a phosphor prepared as stated above and covered on the radiating surface of the InGaN heterostructure, wherein the axial light intensity is: 200≦J≦500cd and the total luminous efficiency ≧60 lm/w.

### DETAILED DESCRIPTION OF THE PREFERRED EMBODIMENT

The main object of the present invention is to eliminate the drawback of YAG (yttrium aluminum garnet) phosphor. To achieve this object, the invention provides a phosphor capable of changing the wavelength of a solid light source that uses rare-earth garnet as the substrate and cerium as the activating agent. The invention is characterized in that the phosphor has added thereto nitrogen (N) and fluorine (F). And the chemical formula of the phosphor is: (ΣLn)₃Al₅O_{12-δ}N⁻³_{δ/2}F⁻¹_{δ/2}, wherein ΣLn=Y_{1-x-y-z}GdₓLu_{y}Ce_{z},

in which, the chemical variation of index: x=0.01˜0.4, y=0.001˜0.1, z=0.01˜0.4, and 6=0.001˜0.005;

in which, the material composition is in conformity with: 0.005≦Ce/(Y+Gd+Lu+Ce)≦0.05;

in which, the material absorbs the short-wave radiation of InGaN LED λ=440˜480 nm, and its composition is in conformity with: 0.02≦Lu/(Y+Gd+Lu+Ce)≦0.10;

in which, the material emits light at yellow-green spectral zone, wavelength λ=530λ590 nm, and ts composition is in conformity with: 0.02≦Gd/(Y+Gd+Lu+Ce)≦0.30;

in which, the luminosity of the material is 290 Q1 360 lm/w, the chemical variation of index is: 0.001≦δ≦0.015, and the content of F⁻ is same;

in which, the material powder has an ellipse-like configuration, powder medium size 1 μgm≦d₅₀≦2 μm, and specific surface area S≧38×10³ cm²/cm³;

in which, the afterglow time of Ce⁺³ is τₑ=72 ns, and when nitrogen (N) in the substrate is greatly increased, the afterglow time will be reduced below 72 ns.

The physical chemistry principle of the composition of the phosphor of the present invention is outlined hereinafter. At first, the YAG:Ce phosphor has a cubic crystal structure. Y⁺³ forms the crystal lattice of cations. The coordinate number of these ions is K=12. In the crystal lattice, Y⁺³ is evenly surrounded by 12 oxygen ions. The added Ce⁺³ occupies the crystal lattice of Y⁺³. The radius of Ce⁺³ and Y⁺³ are δ_{Ce}=1.06 A and δ_{Y}=0.97 A respectively. Under a similar condition, the circumference of Ce⁺³ is slightly widened, and the equilibrium of the circumference of Ce⁺³ remains unchanged. In the garnet crystal lattice, the radiation of the anions shows a homogeneous Diophantine Gaussian curve, having a half width Δ=120 nm.

Due to a series of reasons, the stoichiometric equation of Y₃Al₅O₁₂ is broken. The original oxygen ratio is Y₂O₃:Al₂O₃=3:5. The number of O⁻² that surrounds Y⁺³ is changed from 12 (or 9) to 11 or 10. The vacuum zone that lacks oxygen ions or the lattice junction forms the so-called gap or vacuum junction, referenced by V0. At this time, the field of force of oxygen ions attenuates, resulting in reduced radiation efficiency of Y₃Al₅O₁₂:Ce phosphor. Technically, this happening has a great concern with “dew-point” T=−80° C. dry H₂ used during heat treatment of the phosphor. There is a significant lack of oxygen in dry hydrogen. When operating temperature T>1500° C., Y₂O₃ and Al₂O₃ decompose, and the related equation is: Y₃Al₅O₁₂^{T}→Y₃Al₅O_{12-δ}+^{δ}/₂O₂↑. Because of the said significant gap defect and oxygen material defect in the phosphor, brown yellow is seen in bright yellow. To eliminate oxygen material defect, the invention has N⁻³ and F⁻¹ be added to the phosphor substrate. These ions are similar to oxygen ions in size: τₒ=1.36 A, τ_{N}=1.46 A, τ_{F}=1.33 A, carrying negative charges N⁻³ and F⁻¹. A substitution of oxygen in the phosphor occurs: δO⁻²→^{δ}/₂N⁻³+^{δ}/₂F⁻¹. One half of the oxygen ions in the vaccuum zone is substituted by Nitrogen ions, and the other by fluoride ions. At the same time, the static electric field (or the substitute Ce⁺³) that surrounds Y⁺³ becomes uneven. N⁻³ negative charges build up a strong static electric field that acts upon Ce⁺³. This static electric field is 1.5 times stronger than the field of O⁻². On the other hand, F⁻¹ carries a negative charge around Ce⁺³. Therefore, the strong static electric field of F⁻¹ affects Ce⁺³.

Test of the radiation spectrum of the phosphor prepared according to the present invention indicates the facts stated below. These facts are subject to variation of the internal field of force of the crystal lattice. We believe that this static electric field enhances the radiation strength of Ce⁺³ in (Y,Gd,Lu)₃Al₅O₁₂:Ce. Because of the uneven feature, the static electric field causes a change of the gaussian curve spectrum, and this change describes the radiation of Ce⁺³ in (Y,Gd,Lu)₃Al₅O₁₂:Ce. The maximum value of the spectrum radiation is λ=549nm; the half width is λ_{0.5}=116 nm; the color coordinate of the radiation is: x=0.35, y=0.42. The maximum value of the spectrum of the phosphor (Y,Gd,Lu)₃Al₅O_{12-δ}N⁺³_{δ/2}F⁻¹_{δ/2}:Ce of present invention is λ=549.6 nm, and its strength is L=34000 units (a standard phosphor is L=30000 units). However, there is a substantial change in the formation of the spectrum curve: it has more radiation. The width of half wave is widened λ_{0.5}=122 nm. It is assymetric in red spectra. These three test results show a substantial change after adding of F⁻¹ and N⁻³.

The radiation spectrum of the phosphor prepared according to the present invention is not limited to the aforesaid characteristics. The radiation spectrum of the phosphor prepared according to the present invention also shows the characteristic that the material composition is in conformity with the inequality: 0.005≦Ce/(Y+Gd+Lu+Ce)≦0.05.

This inequality is based on the experimental study of the present invention. It reflects the content of Ce⁺³ in the phosphor substrate. It indicates the best optimal content of Ce⁺³ in the phosphor to be [Ce⁺³]=0.02±0.002 atomic fraction. If the content of Ce⁺³ is below this value, the luminous brightness of the phosphor will be reduced drastically. When the content of Ce⁺³=0.006, the luminous brightness becomes 18000 units. When the content of Ce⁺³ is increased to 0.03 atomic fraction, the phosphor emits bright yellow light of radiation wavelength λ=566 nm. This condition appears during heating of the phosphor, and the short-wave green radiation is disappeared at this time. Thus, when the content of Ce⁺³ is excessively high, a famous phenomenon, i.e., concentration quenching will occur. To prevent concentration quenching, the best optimal Ce⁺³ concentration is necessary.

From the aforesaid test result, it is for sure that the phosphor can be activated by a short-wave light λ=440˜480 nm. However, it is to be understood that the standard material Y₃Al₅O₁₂:Ce can emit light only when activated by a wavelength range λ=450˜475 nm. It is for sure that various short-wave radiations of wavelength about λ=440 nm can emit light only when its composition contains Lu⁺³. On the other hand, the activation of light is seen at the wavelength λ≧475 nm only when the phosphor is added with Gd⁺³. When the maximum value of the radiation λ=460 nm and the halfwidth of the radiation spectrum λ_{0.5}=20˜28 nm, the activation of the phosphor is suitable for an InGaN LED. It is to be understood that the industry at the present time is prepared to fabricate such a LED.

Therefore, the phosphor of the present invention has the characteristic that the composition is in conformity with the inequality: 0.02≦Lu/(Y+Gd+Lu+Ce)≦0.10. 0.005≦(Ce+Yb)/(Y+Lu+Gd+Tb+Ce )≦0.1 from τ=120˜60 ns

When [Lu⁺³]<0.20, there is no any significant change on the band width of the excitation spectrum. When [Lu⁺³]>0.10, the phosphor produces floc-like white light. The initial heterostructure radiation is reducing subject to absorption. As for sure, the best optimal content of Lu⁺³ is [Lu⁺³]=0.04±0.02. At this concentration, the phosphor gives light in the spectral zone of green and yellow, more particularly, in the spectral zone of orange yellow. This luminance is mixed with unabsorbed blue light at a predetermined ratio, producing a white radiation in a variety of cold and warm tones.

We are sure that the maximum value of the wavelength of the photoluminescence of the luminous material according to the present invention is λ=530˜590 nm. When compared to the standard material Y₃Al₅O₁₂:Ce, the luminous material of the present invention has obvious advantages. The light wavelength of standard material Y₃Al₅O₁₂:Ce is 535≦λ≦565 nm. Similar advantages are seen in the phosphor. The content of Gd ions is in confirmity with the inequality: 0.04≦Gd/(Y+Gd+Lu+Ce)≦0.30 atomic fraction.

When the concentration of [Gd⁺³] is below 0.07, the change of the atomic fraction of the radiation spectrum of the phosphor is insignificant. When the content of [Gd⁺³]≧0.3 atomic fraction, the lumen brightness of the phosphor is reduced. From X-ray phase analysis of the material, the trace of a second phase is observed. If the maximum value of the spectrum of the phosphor appears in orange-yellow visible spectrum, the phosphor will produce a white radiation in warm tones.

The color temperature of the best optimal radiation to human eyes is T=3000˜5000K. Further, the radiation brightness of the white LED and the white cold tone radiation produced during the use of the phosphor are kept at a same height. The lumen brightness is assured subject to: B=(JU)×η_{quantum}(λ_{activiation}/λ_{radiation})×Q₁×θ, and

J×U LED electric power;
η_{quantum} internal quantum output;
(λ_{activation}/λ_{radiation}) - - - radiation wavelength and activation wavelenth relationship
λ_{activation}/λ_{radiation}=460/560=0.82 makes sure of activation loss ; light power of lumen equivalent Q₁ under the condition of activation is W_{CB}=1 Watt.

The above literature introduces a big amount of data related to lumen equivalent. When λ=555 nm, Q=683 lm/w, the standard YAG:Ce substrate-based phosphor will have a lumen equivalent value: Q₁=260˜310 lm/w. The lumen equivalent value of the phosphor according to the present invention is calculated, to be 360 lm/w. This maximum value obtained during working has the phosphor of the present invention to provide a radiation of wavelength λ=555 nm. We can obtain transitent equivalent 295 lm/w, 315 lm/w, 335 lm/w, 350 lm/w. The number obtained from the experiment according to the present invention and the product of free fluorine ions obtained from that added to the furnace charge show the same concentration.

This concept is explained hereinafter. To produce the product, the invention added various materials to the furnace charge. Under a predetermined temperature, some materials were changed into a liquid, such as BaF₂(T=1329° C.), however the evaporation temperature of this substance was as high as T=2100° C. while the evaporation temperatures of the other substances were low, for example, the evaporation temperature of AlF₃ was 450° C. Further, when at a high temperature, this substance evaporated (AlF₃)ₛₒₗ→(AlF₃)_{g}^{→}_{←}AlF₂+F and decomposed into fluorine atoms. These fluorine atoms entered the crystal lattice and formed with YAG into a compound. At this time, YAG contained dopants Gd, Lu, Ce, N and F.

The phosphor prepared according to the present invention can be used for making white light radiators as well as CRT screens. For making a CRT screen, the factors of attenuation speed and afterflow lasting time must be taken into account. In a substantial material provided according to the present invention, the time range is T=72˜75 ns, and this value will be relatively reduced when the content of the added nitrous acid compound is increased. When adding LuN of atomic fraction 0.1% to the material, the afterglow lasting time will be T=65 ns. When adding LuN of atomic fraction 0.2% to the material, the afterglow lasting time will be T=62 ns.

A phosphor was made by means of a multi-disperson powder synthesis technique according to the present invention. The powder particles had different sizes. The powder was ground into a 12 or 24-rhombic face profile. Many of the rhombic faces were equalateral hexagonal faces.

A test made on powder dispersion by means of a professional laser instrument shows the result that medium sized powder 1 μm≦d₅₀≦2 μm; the value of specific surface area 23.8×10³ cm²/cm³. The synthesis of the phosphor of the present invention will be filed separately. Therefore, no further description will be given herein. However, it is to be understood that rare-earth oxide (Y₂O₃, Gd₂O₃, Lu₂O₃, CeO₂) and oxide or hydroxide of aluminum (αAl₂O₃,γAl₂O₃, Al(OH)₃) are added to the initial ingredients of the material.

Table I introduces all the phosphor light technique parameter data.

TABLE I

| | | | | Color | |
|---|---|---|---|---|---|
| No | Fluorescent power composition | λ | Q_{L} lm/w | coordinate | |
| 1 | (Y_{0.9}Gd_{0.07}Lu_{0.01}Ce_{0.02})₃Al₅O_{11.95}N_{0.025}F_{0.025} | 545 | 320 | 0.330 | 0.385 |
| 2 | (Y_{0.9}Gd_{0.05}Lu_{0.03}Ce_{0.02})₃Al₅O_{11.99}N_{0.05}F_{0.05} | 542 | 305 | 0.322 | 0.374 |
| 3 | (Y_{0.6}Gd_{0.35}Lu_{0.03}Ce_{0.02})₃Al₅O_{11.99}N_{0.005}F_{0.005} | 568 | 290 | 398 | 495 |
| 4 | (Y_{0.55}Gd_{0.40}Lu_{0.03}Ce_{0.02})₃Al₅O_{11.99}N_{0.005}F_{0.005} | 578 | 292 | 0.410 | 0.520 |
| 5 | (Y_{0.85}Gd_{0.1}Lu_{0.03}Ce_{0.02})₃Al₅O_{11.99}N_{0.005}F_{0.005} | 555 | 360 | 0.39 | 0.48 |
| 6 | (Y_{0.85}Gd_{0.05}Lu_{0.08}Ce_{0.02})₃Al₅O_{11.99}N_{0.005}F_{0.005} | 549 | 323 | 0.36 | 0.44 |
| 7 | (Y_{0.83}Gd_{0.05}Lu_{0.1}Ce_{0.02})₃Al₅O_{14.99}N_{0.005}F_{0.005} | 544 | 300 | 0.340 | 0.410 |
| 8 | (Y_{0.83}Gd_{0.05}Lu_{0.05}Ce_{0.07})₃Al₅O_{11.98}N_{0.01}F_{0.01} | 548 | 305 | 0.375 | 0.444 |
| 9 | (Y_{0.83}Gd_{0.05}Lu_{0.02}Ce_{0.1})₃Al₅O_{11.98}N_{0.01}F_{0.01} | 551 | 318 | 0.380 | 0.450 |
| 10 | (Y_{0.83}Gd_{0.05}Lu_{0.02}Ce_{0.1})₃Al₅O_{11.95}N_{0.025}F_{0.025} | 553 | 335 | 0.390 | 0.460 |
| 11 | (Y,Gd,Lu,Ce)₃Al₅O₁₂ | 554 | 320 | 0.350 | 0.395 |

From Table I, it can be determined that the maximum value of the wavelength of the spectrum of the phosphor according to the present invention is within the range of λ=542˜578nm; the wavelength that takes the major role is λₘₐⱼₒᵣ=545˜568 nm; color coordinate x=0.322˜0.410, and y=0.374˜0.520; spectrum lumen equivalent: Q_{L}=299˜360 lm/w.

The variation of introduced spectrum and light technique characteristics expresses applicability of the phosphor of the present invention. The phosphor and the various InGaN-based semiconductor heterostructures produce white light of various tones: cold white, daylight white and warm white. These show the characteristics of the phosphor in various field.

The heterostructure input power is W=1 w (current 350 mA), the luminous intensity is over 200cd and can reach even 350˜400cd or even 500cd. The total light flux of this design of LED reaches 55˜65 lm, and its lumen efficiency is η=60 lm/w. This lumen efficiency is greater than the parameter value of an energy-saving lamp (η=44˜55 lm/w).

In conclusion, the invention provides a phosphor that can cause a solid light source to change its wavelength, provides anti-heat effect, has a wide spectrum adjustment range under a same excited wavelength range. Further, the phosphor improves yellow, orange-yellow and red visible spectrum lumen efficiency, maintaining the brightness of the white LED when working for a long period of time. Therefore, the invention effectively eliminates the drawbacks of conventional YAG based phosphor.

Although a particular embodiment of the invention has been described in detail for purposes of illustration, various modifications and enhancements may be made without departing from the spirit and scope of the invention.

What is claimed is:

1. A phosphor for use in a short-wave semiconductor light emitting diode, comprising a substrate prepared from an oxide of rear-earth elements of aluminum and an activating agent prepared from cerium, wherein the phosphor contains nitrogen and fluorine and the chemical formula of the phosphor is (ΣLn)₃Al₅O_{12-δ}N³_{δ/2}F⁻¹_{δ/2}, in which ΣLn=Y_{1-x-y-z}GdₓLu_{y}Ce_{z}.

2. The phosphor as claimed in claim 1, wherein the chemical index varies as: x=0.01˜0.4, y=0.001˜0.1, z=0.001˜0.4, and δ=0.001˜0.005.

3. The phosphor as claimed in claim 1, wherein the composition of the phosphor is in conformity with the inequality: 0.005≦Ce/(Y+Gd+Lu+Ce)≦0.05.

4. The phosphor as claimed in claim 1, wherein the material of the phosphor absorbs short-wave λ=440˜480 nm from an InGaN LED, and the composition of the phosphor is in conformity with the inequality: 0.02≦Lu/(Y+Gd+Lu+Ce)≦0.10.

5. The phosphor as claimed in claim 1, wherein the material of the phosphor gives light in yellow green spectral zone of wavelength λ=530˜590nm, and the composition of the phosphor is in conformity with the inequality: 0.05≦Gd/(Y+Gd+Lu+Ce)≦0.30.

6. The phosphor as claimed in claim 1, wherein the material of the phosphor has a lumen equivalent value 290≦Q1≦360 lm/w, the chemical index range is: 0.001≦δ≦0.015, and the substrate material F⁻¹ has the same content.

7. The phosphor as claimed in claim 1, wherein the powder particles of the phosphor have an elliptic shape, and a medium size: 1 μm≦d₅₀≦2 μm, and a specific surface area: S≧38×10³ cm²/cm³.

8. The phosphor as claimed in claim 1, wherein the afterglow time of the radiation of Ce⁺³ is: τₑ=72 ns, and the afterglow time is reduced to below τₑ=72 ns when the nitrogen content is the substrate is increased.

9. A light emitting diode comprising an InGaN heterostructure, and a fluorescent power prepared according to claim 1 and covered on a radiating surface of said InGaN heterostructure, wherein the axial light intensity is: 200≦J≦500 cd and the total luminous efficiency ≧60 lm/w.
